(19) United States
(12) Patent Application Publication
(10) Pub. No.: US 2011/0057818 A1
(43) Pub. Date: Mar. 10, 2011

(54) Apparatus and Method for Encoding and Decoding Signal

(75) Inventors: Yang Won Jung, Seoul (KR); Hyen-O Oh, Gyeonggi-do (KR); Hyo Jin Kim, Seoul (KR); Seung Jong Choi, Seoul (KR); Dong Geum Lee, Seoul (KR); Hong Goo Kang, Seoul (KR); Jae Seong Lee, Seoul (KR)

(73) Assignee: LG ELECTRONICS, INC., Seoul (KR)

(21) Appl. No.: 12/161,162

(22) PCT Filed: Jan. 18, 2007
(86) PCT No.: PCT/KR07/00302

§ 371 Date: Jan. 23, 2009

(51) Int. Cl. H03M 7/00

(52) U.S. Cl. 341/50

(57) ABSTRACT

Encoding and decoding apparatuses and encoding and decoding methods are provided. The decoding method includes extracting a plurality of encoded signals from an input bitstream, determining which of a plurality of decoding methods is to be used to decode each of the encoded signals, decoding the encoded signals using the determined decoding methods, and synthesizing the decoded signals. Accordingly, it is possible to encode signals having different characteristics at an optimum bitrate by classifying the signals into one or more classes according to the characteristics of the signals and encoding each of the signals using an encoding unit that can best serve the class where a corresponding signal belongs. In addition, it is possible to efficiently encode various signals including audio and speech signals.

### TECHNICAL FIELD

The present invention relates to encoding and decoding apparatuses and encoding and decoding methods, and more particularly, to encoding and decoding apparatuses and encoding and decoding methods which can encode or decode signals at an optimum bitrate according to the characteristics of the signals.

### BACKGROUND ART

Conventional audio encoders can provide high-quality audio signals at a high bitrate of 48 kbps or greater, but are inefficient for processing speech signals. On the other hand, conventional speech coders can effectively encode speech signals at a low bitrate of 12 kbps or less, but are insufficient to encode various audio signals.

### DISCLOSURE OF INVENTION

### Technical Problem

The present invention provides encoding and decoding apparatuses and encoding and decoding methods which can encode or decode signals (e.g., speech and audio signals) having different characteristics at an optimum bitrate.

### Technical Solution

According to an aspect of the present invention, there is provided a decoding method, including extracting a plurality of encoded signals from an input bitstream, determining which of a plurality of decoding methods is to be used to decode each of the encoded signals, decoding the encoded signals using the determined decoding methods, and synthesizing the decoded signals.

According to another aspect of the present invention, there is provided a decoding apparatus, including a bit unpacking module which extracts a plurality of encoded signals from an input bitstream, a decoder determination module which determines which of a plurality of decoding units is to be used to decode each of the encoded signals, a decoding module which includes the decoding units and decodes the encoded signals using the determined decoding units, and a synthesization module which synthesizes the decoded signals.

According to another aspect of the present invention, there is provided an encoding method, including dividing an input signal into a plurality of divided signals, determining which of a plurality of encoding methods is to be used to encode each of the divided signals based on characteristics of each of the divided signals, encoding the divided signals using the determined encoding methods, and generating a bitstream based on the encoded divided signals.

According to another aspect of the present invention, there is provided an encoding apparatus, including a signal division module which divides an input signal into a plurality of divided signals, an encoder determination module which determines which of a plurality of encoding units is to be used to encode each of the divided signals based on characteristics of each of the divided signals, an encoding module which includes the encoding units and encodes the divided signals using the determined encoding units, and a bit packing module which generates a bitstream based on the encoded divided signals.

### ADVANTAGEOUS EFFECTS

Accordingly, it is possible to encode signals having different characteristics at an optimum bitrate by classifying the signals into one or more classes according to the characteristics of the signals and encoding each of the signals using an encoding unit that can best serve the class where a corresponding signal belongs. In addition, it is possible to efficiently encode various signals including audio and speech signals.

### BRIEF DESCRIPTION OF THE DRAWINGS

FIG. 1 is a block diagram of an encoding apparatus according to an embodiment of the present invention;

FIG. 2 is a block diagram of an embodiment of a classification module illustrated in FIG. 1;

FIG. 3 is a block diagram of an embodiment of a pre-processing unit illustrated in FIG. 2;

FIG. 4 is a block diagram of an apparatus for calculating the perceptual entropy of an input signal according to an embodiment of the present invention;

FIG. 5 is a block diagram of another embodiment of the classification module illustrated in FIG. 1;

FIG. 6 is a block diagram of an embodiment of a signal division unit illustrated in FIG. 5;

FIGS. 7 and 8 are diagrams for explaining methods of merging a plurality of divided signals according to embodiments of the present invention;

FIG. 9 is a block diagram of another embodiment of the signal division unit illustrated in FIG. 5;

FIG. 10 is a diagram for explaining a method of dividing an input signal into a plurality of divided signals according to an embodiment of the present invention;

FIG. 11 is a block diagram of an embodiment of a determination unit illustrated in FIG. 5;

FIG. 12 is a block diagram of an embodiment of an encoding unit illustrated in FIG. 1;

FIG. 13 is a block diagram of another embodiment of the encoding unit illustrated in FIG. 1;

FIG. 14 is a block diagram of an encoding apparatus according to another embodiment of the present invention;

FIG. 15 is a block diagram of a decoding apparatus according to an embodiment of the present invention; and

FIG. 16 is a block diagram of an embodiment of a synthesization unit illustrated in FIG. 15.

### BEST MODE FOR CARRYING OUT THE INVENTION

The present invention will hereinafter be described more fully with reference to the accompanying drawings, in which exemplary embodiments of the invention are shown.

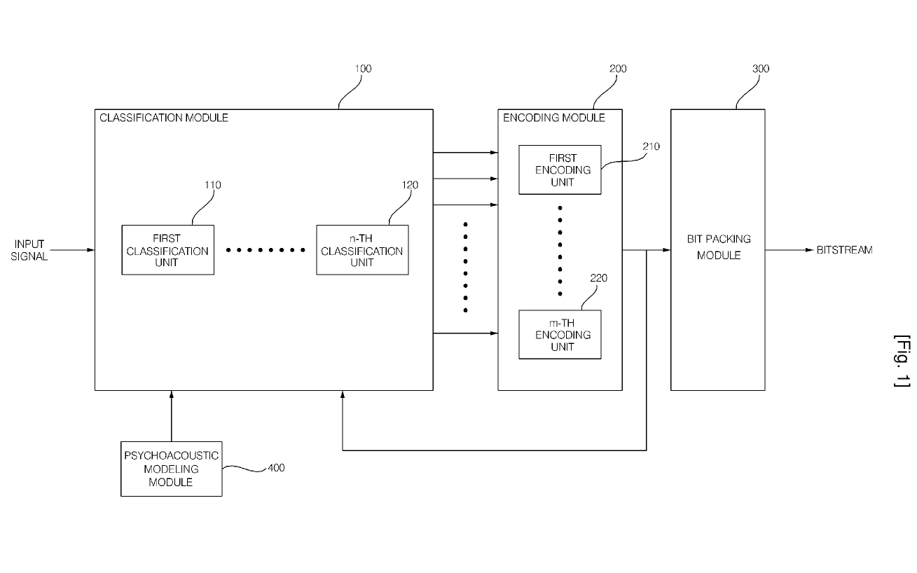

FIG. 1 is a block diagram of an encoding apparatus according to an embodiment of the present invention. Referring to FIG. 1, the encoding apparatus includes a classification module 100, an encoding module 200, and a bit packing module 300.

The encoding module 200 includes a plurality of first through m-th encoding units 210 and 220 which perform different encoding methods.

The classification module 100 divides an input signal into a plurality of divided signals and matches each of the divided signals to one of the first through m-th encoding units 210 and 220. Some of the first through m-th encoding units 210 and 220 may be matched to two or more divided signals or no divided signal at all.

The classification module 100 may allocate a bit quantity to encode each of the divided signals or determine the order in which the divided signals are to be encoded.

The encoding module 200 encodes each of the divided signals using whichever of the first through m-th encoding units 210 and 220 is matched to a corresponding divided signal. The classification module 100 analyzes the characteristics of each of the divided signals and chooses one of the first through m-th encoding units 210 and 220 that can encode each of the divided signals according to the results of the analysis most efficiently.

An encoding unit that can encode a divided signal most efficiently may be regarded as being capable of achieving a highest compression efficiency.

For example, a divided signal that can be modelled easily as a coefficient and a residue can be efficiently encoded by a speech coder, and a divided signal that cannot be modelled easily as a coefficient and a residue can be efficiently encoded by an audio encoder.

If the ratio of the energy of a residue obtained by modelling a divided signal to the energy of the divided signal is less than a predefined threshold, the divided signal may be regarded as being a signal that can be modelled easily.

Since a divided signal that exhibits a high redundancy on a time axis can be well modeled using a linear predicted method in which a current signal is predicted based on a previous signal, it can be encoded most efficiently by a speech coder that uses a linear prediction coding method.

The bit packing module 300 generates a bitstream to be transmitted based on encoded divided signals provided by the encoding module 200 and additional encoding information regarding the encoded divided signals. The bit packing module 300 may generate a bitstream having a variable bitrate using a bit-plain method or a bit sliced arithmetic encoding method.

Divided signals or bandwidths that are not encoded due to bitrate restrictions may be restored from decoded signals or bandwidths provided by a decoder using an interpolation, extrapolation, or replication method. Also, compensation information regarding divided signals that are not encoded may be included in a bitstream to be transmitted.

Referring to FIG. 1, the classification module 110 may include a plurality of first through n-th classification units 110 and 120. Each of the first through n-th classification units 110 and 120 may divide the input signal into a plurality of divided signals, converts a domain of the input signal, extracts the characteristics of the input signal, classifies the input signal according to the characteristics of the input signal, or matches the input signal to one of the first through m-th encoding units 210 and 220.

One of the first through n-th classification units 110 and 120 may be a pre-processing unit which performs a pre-processing operation on the input signal so that the input signal can be converted into a signal that can be efficiently encoded. The pre-processing unit may divide the input signal into a plurality of components, for example, a coefficient component and a signal component, and may perform a pre-processing operation on the input signal before the other classification units perform their operations.

The input signal may be pre-processed selectively according to the characteristics of the input signal, external environmental factors, and a target bitrate, and only some of a plurality of divided signals obtained from the input signal may be selectively pre-processed.

The classification module 100 may classify the input signal according to perceptual characteristic information of the input signal provided by a psychoacoustic modeling module 400. Examples of the perceptual characteristic information include a masking threshold, a signal-to-mask ratio (SMR), and perceptual entropy.

In other words, the classification module 100 may divide the input signal into a plurality of divided signals or may match each of the divided signals to one or more of the first through m-th encoding units 210 through 220 according to the perceptual characteristic information of the input signal, for example, a masking threshold and an SNR of the input signal.

In addition, the classification module 100 may receive information such as the tonality, the zero crossing rate (ZCR), and a linear prediction coefficient of the input signal, and classification information of previous frames, and may classify the input signal according to the received information.

Referring to FIG. 1, encoded result information output by the encoding module 200 may be fed back to the classification module 100.

Once the input signal is divided into a plurality of divided signals by the classification module 100 and it is determined by which of the first through m-th encoding units 210 and 220, with what bit quantity, and in what order the divided signals are to be encoded, the divided signals are encoded according to the results of the determination. A bit quantity actually used for encoding each of the divided signals may not necessarily be the same as a bit quantity allocated by the classification module 100.

Information specifying the difference between the actually used bit quantity and the allocated bit quantity may be fed back to the classification module 100 so that the classification module 100 can increase the allocated bit quantity for other divided signals. If the actually used bit quantity is greater than the allocated bit quantity, the classification module 100 may reduce the allocated bit quantity for other divided signals.

An encoding unit that actually encodes a divided signal may not necessarily be the same as an encoding unit that is matched to the divided signal by the classification module 100. In this case, information may be fed back to the classification module 100, indicating that an encoding unit that actually encodes a divided signal is different from an encoding unit matched to the divided signal by the classification module 100. Then, the classification module 100 may match the divided signal to an encoding unit, other than the encoding unit previously matched to the divided signal.

The classification module 100 may divide the input signal again into a plurality of divided signals according to encoded result information fed back thereto. In this case, the classification module 100 may obtain a plurality of divided signals having a different structure from that of the previously-obtained divided signals.

If an encoding operation chosen by the classification module 100 differs from an encoding operation that is actually performed, information regarding the differences therebetween may be fed back to the classification module 100 so that the classification module 100 can determine encoding operation-related information again.

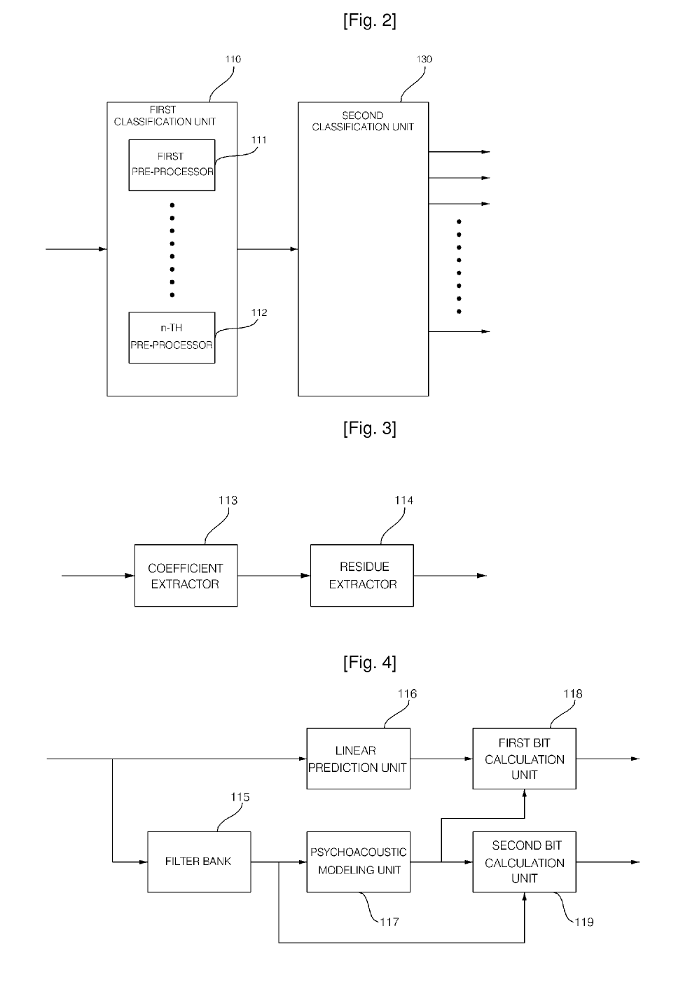

FIG. 2 is a block diagram of an embodiment of the classification module 100 illustrated in FIG. 1. Referring to FIG. 2, the first classification unit may be a pre-processing unit which performs a pre-processing operation on an input signal so that the input signal can be effectively encoded.

Referring to FIG. 2, the first classification unit 110 may include a plurality of first through n-th pre-processors 111 and 112 which perform different pre-processing methods. The first classification unit 110 may use one of the first through n-th pre-processors 111 and 112 to perform pre-processing on an input signal according to the characteristics of the input signal, external environmental factors, and a target bitrate. Also, the first classification unit 110 may perform two or more pre-processing operations on the input signal using the first through n-th pre-processors 111 and 112.

FIG. 3 is a block diagram of an embodiment of the first through n-th pre-processors 111 and 112 illustrated in FIG. 2. Referring to FIG. 3, a pre-processor includes a coefficient extractor 113 and a residue extractor 114.

The coefficient extractor 113 analyzes an input signal and extracts from the input signal a coefficient representing the characteristics of the input signal. The residue extractor 114 extracts from the input signal a residue with redundant components removed therefrom using the extracted coefficient.

The pre-processor may perform a linear prediction coding operation on the input signal. In this case, the coefficient extractor 113 extracts a linear prediction coefficient from the input signal by performing linear prediction analysis on the input signal, and the residue extractor 114 extracts a residue from the input signal using the linear prediction coefficient provided by the coefficient extractor 113. The residue with redundancy removed therefrom may have the same format as white noise.

A linear prediction analysis method according to an embodiment of the present invention will hereinafter be described in detail.

A predicted signal obtained by linear prediction analysis may be comprised of a linear combination of previous input signals, as indicated by Equation (1):

$$\hat{x} ( n ) = {\sum }_{j = 1}^{p} {α}_{j} x ( n - j ) \qquad MathFigure 1$$

where p indicates a linear prediction order, ₁ through ₚ indicate linear prediction coefficients that are obtained by minimizing a mean square error (MSE) between an input signal and an estimated signal.

A transfer function P(z) for linear prediction analysis may be represented by Equation (2):

$$P ( z ) = {\sum }_{k = 1}^{p} {α}_{k} {z}^{- k} \qquad MathFigure 2$$

Referring to FIG. 3, the pre-processor may extract a linear prediction coefficient and a residue from an input signal using a warped linear prediction coding (WLPC) method, which is another type of linear prediction analysis. The WLPC method may be realized by substituting an all-pass filter having a transfer function A(z) for a unit delay Z⁻¹. The transfer function A(z) may be represented by Equation (3):

$$A ( z ) = [ \frac{{z}^{- 1} - λ}{1 - λ {z}^{- 1}} ] \qquad MathFigure 3$$

where indicates an all-pass coefficient. By varying the all-pass coefficient, it is possible to vary the resolution of a signal to be analyzed. For example, if a signal to be analyzed is highly concentrated on a certain frequency band, e.g., if the signal to be analyzed is an audio signal which is highly concentrated on a low frequency band, the signal to be analyzed may be efficiently encoded by setting the all-pass coefficient such that the resolution of low frequency band signals can be increased.

In the WLPC method, low-frequency signals are analyzed with higher resolution than high-frequency signals. Thus, the WLPC method can achieve high prediction performance for low-frequency signals and can better model low-frequency signals.

The all-pass coefficient may be varied along a time axis according to the characteristics of an input signal, external environmental factors, and a target bitrate. If the all-pass coefficient varies over time, an audio signal obtained by decoding may be considerably distorted. Thus, when the all-pass coefficient varies, a smoothing method may be applied to the all-pass coefficient so that the all-pass coefficient can vary gradually, and that signal distortion can be minimized. The range of values that can be determined as a current all-pass coefficient value may be determined by previous all-pass coefficient values.

A masking threshold, instead of an original signal, may be used as an input for the estimation of a linear prediction coefficient. More specifically, a masking threshold may be converted into a time-domain signal, and WLPC may be performed using the time-domain signal as an input. The prediction of a linear prediction coefficient may be further performed using a residue as an input. In other words, linear prediction analysis may be performed more than one time, thereby obtaining a further whitened residue.

Referring to FIG. 2, the first classification unit 110 may include a first pre-processor 111 which performs linear prediction analysis described above with reference to Equations (1) and (2), and a second pre-processor (not shown) which performs WLPC. The first classification unit 100 may choose one of the first processor 111 and the second pre-processor or may decide not to perform linear prediction analysis on an input signal according to the characteristics of the input signal, external environmental factors, and a target bitrate.

If the all-pass coefficient has a value of 0, the second pre-processor may be the same as the first pre-processor 111. In this case, the first classification unit 110 may include only the second pre-processor, and choose one of the linear prediction analysis method and the WLPC method according to the value of the all-pass coefficient. Also, the first classification unit 110 may perform linear prediction analysis or whichever of the linear prediction analysis method and the WLPC method is chosen in units of frames.

Information indicating whether to perform linear prediction analysis and information indicating which of the linear prediction analysis method and the WLPC methods is chosen may be included in a bitstream to be transmitted.

The bit packing module 300 receives from the first classification unit 110 a linear prediction coefficient, information indicating whether to perform linear prediction coding, and information identifying a linear prediction encoder that is actually used. Then, the bit packing module 300 inserts all the received information into a bitstream to be transmitted.

A bit quantity needed for encoding an input signal into a signal having a sound quality almost indistinguishable from that of the original input signal may be determined by calculating the perceptual entropy of the input signal.

FIG. 4 is a block diagram of an apparatus for calculating perceptual entropy according to an embodiment of the present invention. Referring to FIG. 4, the apparatus includes a filter bank 115, a linear prediction unit 116, a psychoacoustic modeling unit 117, a first bit calculation unit 118, and a second bit calculation unit 119.

The perceptual entropy PE of an input signal may be calculated using Equation (4):

$$P E = \frac{1}{2 π} {\int }_{0}^{π} max [ 0 , {log}_{2} \frac{X ( {e}^{j w} )}{T ( {e}^{j w} )} ] d w ( bit \text{/} sample ) \qquad MathFigure 4$$

where X(e ^{jw}) indicates the energy level of the original input signal, and T(e^{jw}) indicates a masking threshold.

In a WLPC method that involves the use of an all-pass filter, the perceptual entropy of an input signal may be calculated using the ratio of the energy of a residue of the input signal and a masking threshold of the residue. More specifically, an encoding apparatus that uses the WLPC method may calculate perceptual entropy PE of an input signal using Equation (5):

$$P E = \frac{1}{2 π} {\int }_{0}^{π} max [ 0 , {log}_{2} \frac{R ( {e}^{j w} )}{{T}^{1} ( {e}^{j w} )} ] d w ( bit \text{/} sample ) \qquad MathFigure 5$$

where R(e^{jw}) indicates the energy of a residue of the input signal and T(e^{jw}) indicates a masking threshold of the residue.

The masking threshold T(e^{jw}) may be represented by Equation (6):

MathFigure 6

T′(e^{JW})=T(e^{JW})/|H(e^{JW})|²

where T(e^{jw}) indicates a masking threshold of an original signal and H(e^{jw}) indicates a transfer function for WLPC. The psychoacoustic modeling unit 320 may calculate the masking threshold T(e^{jw}) using the masking threshold T(e^{jw}) in a scale-factor band domain and using the transfer function H(e^{jw}).

Referring to FIG. 4, the first bit calculation unit 118 receives a residue obtained by WLPC performed by the linear prediction unit 116 and a masking threshold output by the psychoacoustic modeling unit 117. The filter bank 116 may perform frequency conversion on an original signal, and the result of the frequency conversion may be input to the psychoacoustic modeling unit 117 and the second bit calculation unit 119. The filter bank 115 may perform Fourier transform on the original signal.

The first bit calculation unit 118 may calculate perceptual entropy using the ratio of a masking threshold of the original signal divided by a spectrum of a transfer function of a WLPC synthesis filter and the energy of the residue.

Warped perceptual entropy WPE of a signal which is divided into 60 or more non-uniform partition bands with different bandwidths may be calculated using WLPC, as indicated by Equation (7):

$$W P E = - {\sum }_{b = 1}^{bmax} ( {w}_{high} ( b ) - {w}_{low} ( b ) ) \cdot {log}_{10} ( \frac{{nb}_{res} ( b )}{{e}_{res} ( b )} ) \\ {e}_{res} ( b ) = {\sum }_{w = {w}_{low} ( b )}^{{w}_{high} ( b )} {res ( w )}^{2} \\ {nb}_{res} ( b ) = {\sum }_{w = {w}_{low} ( b )}^{{w}_{high} ( b )} \frac{{nb}_{linear} ( w )}{{h ( w )}^{2}} \qquad MathFigure 7$$

where b indicates an index of a partition band obtained using a psychoacoustic model, eᵣₑₛ(b) indicates the sum of the energies of residues in the partition band b, w_low(b) and w_high(b) respectively indicate lowest and highest frequencies in the partition band b, nbₗᵢₙₑₐᵣ(w) indicates a masking threshold of a linearly mapped partition band, h(w)² indicates a linear prediction coding (LPC) energy spectrum of a frame, and nbᵣₑₛ(w) indicates a linear masking threshold corresponding to a residue.

On the other hand, the warped perceptual entropy WPE_{sub} of a signal which is divided into 60 or more uniform partition bands with the same bandwidth may be calculated using WLPC, as indicated by Equation (8):

$${nb}_{sub} ( s ) = {min}_{{s}_{low} ( s ) < w < {s}_{high} ( s )} ( \frac{{nb}_{linear} ( w )}{{h ( w )}^{2}} ) \\ W P {E}_{sub} = - {\sum }_{s = 1}^{smax} ( {s}_{high} ( s ) - {s}_{low} ( s ) ) \cdot {log}_{10} ( \frac{{nb}_{sub} ( s )}{{e}_{sub} ( s )} ) \\ {e}_{sub} ( s ) = {\sum }_{w = {s}_{low} ( s )}^{{s}_{high} ( s )} {res ( w )}^{2} \qquad MathFigure 8$$

where s indicates an index of a linearly partitioned sub-band, s_{low(w)} and s_{high(w)} respectively indicate lowest and highest frequencies in the linearly partitioned sub-band s, nb_{sub}(s) indicates a masking threshold of the linearly partitioned sub-band s, and e_{sub}(s) indicates the energy of the linearly partitioned sub-band s, i.e., the sum of the frequencies in the linearly partitioned sub-band s. The masking threshold nb_{sub}(s) is a minimum of a plurality of masking thresholds in the linearly partitioned sub-band s.

Perceptual entropy may not be calculated for bands with the same bandwidth and with thresholds higher than the sum of input spectrums. Thus, the warped perceptual entropy WPE_{sub} of Equation (8) may be lower than warped perceptual entropy WPE of Equation (7), which provides high resolution for low frequency bands.

Warped perceptual entropy WPE_{sf} may be calculated for scale-factor bands with different bandwidths using WLPC, as indicated by Equation (9):

$${nb}_{sf} ( s ) = {min}_{{sf}_{low} ( s ) < w < {sf}_{high} ( s )} ( \frac{{nb}_{linear} ( w )}{{h ( w )}^{2}} ) \\ {WPE}_{sf} = - {\sum }_{f = 1}^{fmax} ( {s}_{high} ( f ) - {s}_{low} ( f ) ) \cdot {log}_{10} ( \frac{{nb}_{sf} ( f )}{{e}_{sf} ( f )} ) \\ {e}_{sf} ( s ) = {\sum }_{w = {sf}_{low} ( s )}^{{sf}_{high} ( s )} {res ( w )}^{2} \qquad MathFigure 9$$

where f indicates an index of a scale-factor band, nb_{sf}(f) indicates a minimum masking threshold of the scale-factor band f, WPE_{sf} indicates the ratio of an input signal of the scale-factor band f and a masking threshold of the scale-factor band f, and e_{sf}(s) indicates the sum of all the frequencies in the scale-factor band f, i.e., the energy of the scale-factor band f.

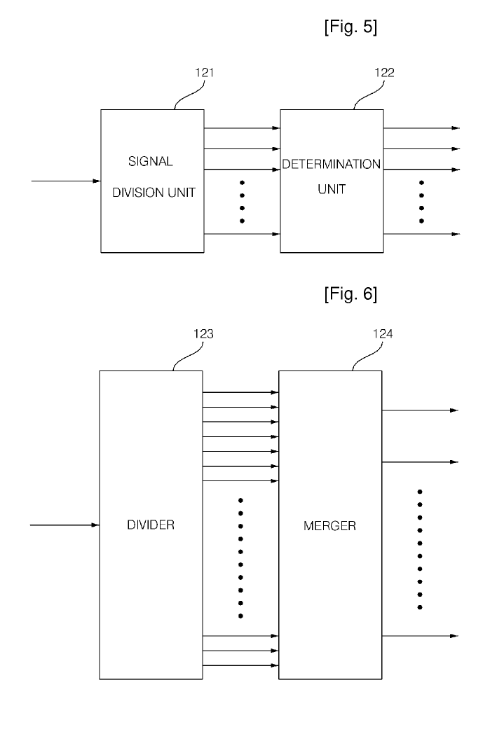

FIG. 5 is a block diagram of another embodiment of the classification module 100 illustrated in FIG. 1. Referring to FIG. 5, a classification module includes a signal division unit 121 and a determination unit 122.

More specifically, the signal division unit 121 divides an input signal into a plurality of divided signals. For example, the signal division unit 121 may divide the input signal into a plurality of frequency bands using a sub-band filter. The frequency bands may have the same bandwidth or different bandwidths. As described above, a divided signal may be encoded separately from other divided signals by an encoding unit that can best serve the characteristics of the divided signal.

The signal division unit 121 may divide the input signal into a plurality of divided signals, for example, a plurality of band signals, so that interference between the band signals can be minimized. The signal division unit 121 may have a dual filter bank structure. In this case, the signal division unit 121 may further divide each of the divided signals.

Division information regarding the divided signals obtained by the signal division unit 121, for example, the total number of divided signals and band information of each of the divided signals, may be included in a bitstream to be transmitted. A decoding apparatus may decode the divided signals separately and synthesize the decoded signals with reference to the division information, thereby restoring the original input signal.

The division information may be stored as a table. A bitstream may include identification information of a table used to divide the original input signal.

The importance of each of the divided signals (e.g., a plurality of frequency band signals) to the quality of sound may be determined, and bitrate may be adjusted for each of the divided signals according to the results of the determination. More specifically, the importance of a divided signal may be defined as a fixed value or as a non-fixed value that varies according to the characteristics of an input signal for each frame.

If speech and audio signals are mixed into the input signal, the signal division unit 121 may divide the input signal into a speech signal and an audio signal according to the characteristics of speech signals and the characteristics of audio signals.

The determination unit 122 may determine which of the first through m-th encoding units 210 and 220 in the encoding module 200 can encode each of the divided signals most efficiently.

The determination unit 122 classifies the divided signals into a number of groups. For example, the determination unit 122 may classify the divided signals into N classes, and determine which of the first through m-th encoding units 210 and 220 is to be used to encode each of the divided signals by matching each of the N classes to one of the first through m-th encoding units 210 and 220.

More specifically, given that the encoding module 200 includes the first through m-th encoding units 210 and 220, the determination unit 122 may classify the divided signals into first through m-th classes, which can be encoded most efficiently by the first through m-th encoding units 210 and 220, respectively.

For this, the characteristics of signals that can be encoded most efficiently by each of the first through m-th encoding units 210 and 220 may be determined in advance, and the characteristics of the first through m-th classes may be defined according to the results of the determination. Thereafter, the determination unit 122 may extract the characteristics of each of the divided signals and classify each of the divided signals into one of the first through m-th classes that shares the same characteristics as a corresponding divided signal according to the results of the extraction.

Examples of the first through m-th classes include a voiced speech class, a voiceless speech class, a background noise class, a silence class, a tonal audio class, a non-tonal audio class, and a voiced speech/audio mixture class.

The determination unit 122 may determine which of the first through m-th encoding units 210 and 220 is to be used to encode each of the divided signals by referencing perceptual characteristic information regarding the divided signals provided by the psychoacoustic modeling module 400, for example, the masking thresholds, SMRs, or perceptual entropy levels of the divided signals.

The determination unit 122 may determine a bit quantity for encoding each of the divided signals or determine the order in which the divided signals are to be encoded by referencing the perceptual characteristic information regarding the divided signals.

Information obtained by the determination performed by the determination unit 122, for example, information indicating by which of the first through m-th encoding units 210 and 220 and with what bit quantity each of the divided signals is to be encoded and information indicating the order in which the divided signals are to be encoded, may be included in a bitstream to be transmitted.

FIG. 6 is a block diagram of an embodiment of the signal division unit 121 illustrated in FIG. 5. Referring to FIG. 6, a signal division unit includes a divider 123 and a merger 124.

The divider 123 may divide an input signal into a plurality of divided signals. The merger 124 may merge divided signals having similar characteristics into a single signal. For this, the merger 124 may include a synthesis filter bank.

For example, the divider 123 may divide an input signal into 256 bands. Of the 256 bands, those having similar characteristics may be merged into a single band by the merger 124.

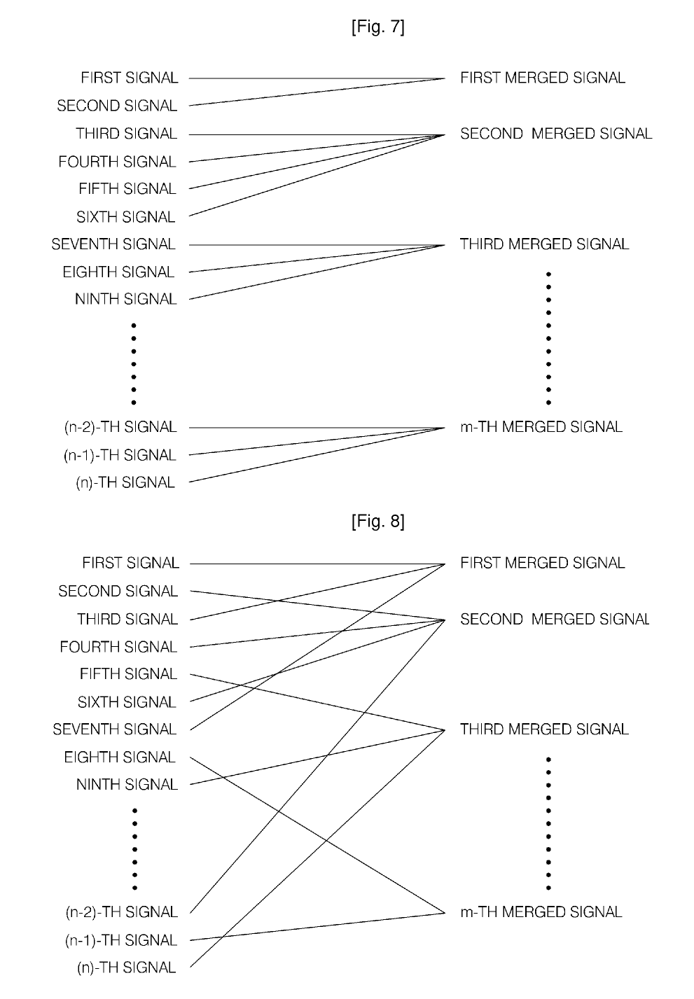

Referring to FIG. 7, the merger 124 may merge a plurality of divided signals that are adjacent to one another into a single merged signal. In this case, the merger 124 may merge a plurality of adjacent divided signals into a single merged signal according to a predefined rule without regard to the characteristics of the adjacent divided signals.

Alternatively, referring to FIG. 8, the merger 124 may merge a plurality of divided signals having similar characteristics into a single merged signal, regardless of whether the divided signals are adjacent to one another. In this case, the merger 124 may merge a plurality of divided signals that can be efficiently encoded by the same encoding unit into a single merged signal.

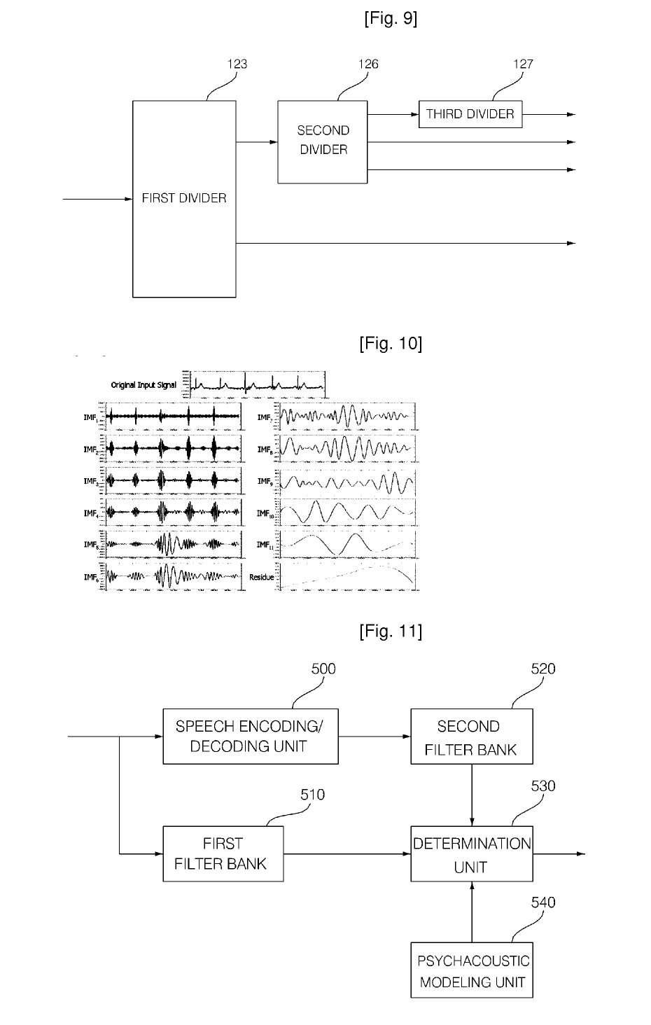

FIG. 9 is a block diagram of another embodiment of the signal division unit 121 illustrated in FIG. 5. Referring to FIG. 9, a signal division unit includes a first divider 125, a second divider 126, and a third divider 127.

More specifically, the signal division unit 121 may hierarchically divide an input signal. For example, the input signal may be divided into two divided signals by the first divider 125, one of the two divided signals may be divided into three divided signals by the second divider 126, and one of the three divided signals may be divided into three divided signals by the third divider 127. In this manner, the input signal may be divided into a total of 6 divided signals. The signal division unit 121 may hierarchically divide the input signal into a plurality of bands with different bandwidths.

In the embodiment illustrated in FIG. 9, an input signal is divided according to a 3-level hierarchy, but the present invention is not restricted thereto. In other words, an input signal may be divided into a plurality of divided signals according to a 2-level or 4 or more-level hierarchy.

One of the first through third dividers 125 through 127 in the signal division unit 121 may divide an input signal into a plurality of time-domain signals.

FIG. 10 explains an embodiment of the division of an input signal into a plurality of divided signals by the signal division unit 121.

Speech or audio signals are generally stationary during a short frame length period. However, speech or audio signals may have non-stationary characteristics sometimes, for example, during a transition period.

In order to effectively analyze non-stationary signals and enhance the efficiency of encoding such non-stationary signals, the encoding apparatus according to the present embodiment may use a wavelet or empirical mode decomposition (EMD) method. In other words, the encoding apparatus according to the present embodiment may analyze the characteristics of an input signal using an unfixed transform function. For example, the signal division unit 121 may divide an input signal into a plurality of bands with variable bandwidths using a non-fixed frequency band sub-band filtering method.

A method of dividing an input signal into a plurality of divided signals through EMD will hereinafter be described in detail.

In the EMD method, an input signal may be decomposed into one or more intrinsic mode functions (IMFs). An IMF must satisfy the following conditions: the number of extrema and the number of zero crossings must either be equal or differ at most by one; and the mean value of an envelope determined by local maxima and an envelope determined by local minima is zero.

An IMF represents a simple oscillatory mode similar to a component in a simple harmonic function, thereby making it possible to effectively decompose an input signal using the EMD method.

More specifically, in order to extract an IMF from an input signal s(t), an upper envelope may be produced by connecting all local extrema determined by local maxima of the input signal s(t) using a cubic spline interpolation method, and a lower envelope may be produced by connecting all local extrema determined by local minima of the input signal s(t) using the cubic spline interpolation method. All values that the input signal s(t) may have may be between the upper envelope and the lower envelope.

Thereafter, the mean value m(t) of the upper envelope and the lower envelope may be calculated. Thereafter, a first component h₁(t) may be calculated by subtracting the mean value m(t) from the input signal s(t), as indicated by Equation (10):

MathFigure 10

s(t)−m₁(t)=h₁(t)

If the first component h₁(t) does not satisfy the above-mentioned IMF conditions, the first component h₁(t) may be determined as being the same as the input signal s(t), and the above-mentioned operation may be performed again until a first IMF C₁(t) that satisfies the above-mentioned IMF conditions is obtained.

Once the first IMF C₁(t) is obtained, a residue r₁(t) is obtained by subtracting the first IMF C₁(t), as indicated by Equation (11):

MathFigure 11

s(t)−c₁(t)=r₁(t)

Thereafter, the above-mentioned IMF extraction operation may be performed again using the residue r₁(t) as a new input signal, thereby obtaining a second IMF C₂(t) and a residue r₂(t).

If a residue rₙ(t) obtained during the above-mentioned IMF extraction operation has a constant value or is either a monotonously increasing function or a single-period function with only one extremum or no extremum at all, the above-mentioned IMF extraction operation may be terminated.

As a result of the above-mentioned IMF extraction operation, the input signal s(t) may be represented by the sum of a plurality of IMFs C₀(t) through C_{M} (t) and a final residue rₘ(t), as indicated by Equation (12):

$$s ( t ) = {\sum }_{m = 0}^{M} {C}_{m} ( t ) + {r}_{m} ( t ) \qquad MathFigure 12$$

where M indicates the total number of IMFs extracted. The final residue rₘ(t) may reflect the general characteristics of the input signal s(t).

FIG. 10 illustrates eleven IMFs and a final residue obtained by decomposing an original input signal using the EMD method. Referring to FIG. 10, the frequency of an IMF obtained from the original input signal at an early stage of IMF extraction is higher than the frequency of an IMF obtained from the original input signal at a later stage of the IMF extraction.

IMF extraction may be simplified using a standard deviation SD between a previous residue h₁₍ₖ₋₁₎ and a current residue h₁ₖ, as indicated by Equation (13):

$$S D = {\sum }_{t = 0}^{T} [ \frac{{\vert {h}_{1 ( k - 1 )} ( t ) - {h}_{1 k} ( t ) \vert}^{2}}{{h}_{1 ( k - 1 )}^{2} ( t )} ] \qquad MathFigure 13$$

If the standard deviation SD is less than a reference value, for example, 0.3, the current residue h₁ₖ may be regarded as an IMF.

In the meantime, a signal x(t) may be transformed into an analytic signal by Hilbert Transform, as indicated by Equation (14):

MathFigure 14

z(t)=x(t)+jH{x(t)}=a(t)e^{jθ(t)}

where (t) indicates an instantaneous amplitude, (t) indicates an instantaneous phase, and H{ } indicates Hilbert Transform.

As a result of Hilbert Transform, an input signal may be converted into an analytic signal consisting of a real component and an imaginary component.

By applying Hilbert Transform to a signal with an average of 0, frequency components that can provide high resolution for both time and frequency domains can be obtained.

It will hereinafter be described in detail how the determination unit 122 illustrated in FIG. 4 determines which of a plurality of encoding units is to be used to encode each of a plurality of divided signals obtained by decomposing an input signal.

The determination unit 122 may determine which of a speech coder and an audio encoder can encode each of the divided signals more efficiently. In other words, the determination unit 122 may decide to encode divided signals that can be efficiently encoded by a speech coder using whichever of the first through m-th encoding units 210 and 220 is a speech coder and decide to encode divided signals that can be efficiently encoded by an audio encoder using whichever of the first through m-th encoding units 210 and 220 is an audio encoder.

It will hereinafter be described in detail how the determination unit 122 determines which of a speech coder and an audio encoder can encode a divided signal more efficiently.

The determination unit 122 may measure the variation in a divided signal and determine that the divided signal can be encoded more efficiently by a speech coder than by an audio encoder if the result of the measurement is greater than a predefined reference value.

Alternatively, the determination unit 122 may measure a tonal component included in a certain part of a divided signal and determine that the divided signal can be encoded more efficiently by an audio encoder than by a speech coder if the result of the measurement is greater than a predefined reference value.

FIG. 11 is a block diagram of an embodiment of the determination unit 122 illustrated in FIG. 5. Referring to FIG. 11, a determination unit includes a speech encoding/decoding unit 500, a first filter bank 510, a second filter bank 520, a determination unit 530, and a psychoacoustic modeling unit 540.

The determination unit illustrated in FIG. 11 may determine which of a speech coder and an audio encoder can encode each divided signal more efficiently.

Referring to FIG. 11, an input signal is encoded by the speech encoding/decoding unit 500, and the encoded signal is decoded by the speech encoding/decoding unit 500, thereby restoring the original input signal. The speech encoding/decoding unit 500 may include an adaptive multi-rate wideband (AMR-WB) speech encoder/decoder, and the AMR-WB speech encoder/decoder may have a code-excited linear predictive (CELP) structure.

The input signal may be down-sampled before being input to the speech encoding/decoding unit 500. A signal output by the speech encoding/decoding unit 500 may be up-sampled, thereby restoring the input signal.

The input signal may be subjected to frequency conversion by the first filter bank 510.

The signal output by the speech encoding/decoding unit 500 is converted into a frequency-domain signal by the second filter bank 520. The first filter bank 510 or the second filter bank 520 may perform cosine transform, for example, modified discrete transform (MDCT), on a signal input thereto.

A frequency component of the original input signal output by the first filter bank 510 and a frequency component of the restored input signal output by the second filter bank 520 are both input to the determination unit 530. The determination unit 530 may determine which of a speech coder and an audio encoder can encode the input signal more efficiently based on the frequency components input thereto.

More specifically, the determination unit 530 may determine which of a speech coder and an audio encoder can encode the input signal more efficiently based on the frequency components input thereto by calculating perceptual entropy PEᵢ of each of the frequency components, using Equation (15):

$$P {E}_{i} = {\sum }_{j = {j}_{low} ( i )}^{{j}_{high} ( i )} N ( j ) \\ where \\ N ( j ) = \{ \begin{matrix}0 , & x ( j ) = 0 \\ {log}_{2} ( 2 \vert nint ( \frac{x ( j )}{δ} ) \vert + 1 ) , & x ( j ) \neq 0\end{matrix} \qquad MathFigure 15$$

where x(j) indicates a coefficient of a frequency component, j indicates an index of the frequency component, indicates quantization step size, nint( ) is a function that returns the nearest integer to its argument, and j_{low(i)} and j_{high(i)} are a beginning frequency index and an ending frequency index, respectively, of a scale-factor band.

The determination unit 530 may calculate the perceptual entropy of the frequency component of the original input signal and the perceptual entropy of the frequency component of the restored input signal using Equation (15), and determine which of an audio encoder and a speech coder is more efficient for use in encoding the input signal based on the results of the calculation.

For example, if the perceptual entropy of the frequency component of the original input signal is less than the perceptual entropy of the frequency component of the restored input signal, the determination unit 530 may determine that the input signal can be more efficiently encoded by an audio encoder than by a speech coder. On the other hand, if the perceptual entropy of the frequency component of the restored input signal is less than the perceptual entropy of the frequency component of the original input signal, the determination unit 530 may determine that the input signal can be encoded more efficiently by a speech coder than by an audio encoder.

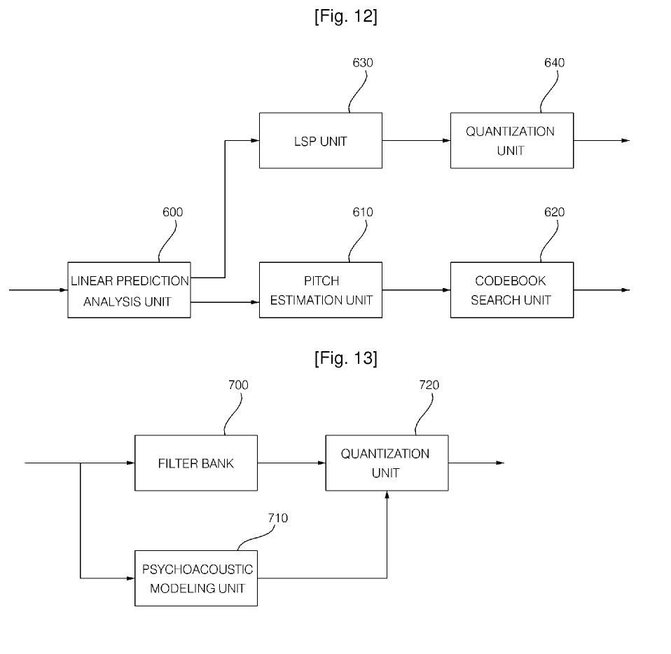

FIG. 12 is a block diagram of an embodiment of one of the first through m-th encoding units 210 and 220 illustrated in FIG. 1. The encoding unit illustrated in FIG. 12 may be a speech coder.

In general, speech coders can perform LPC on an input signal in units of frames and extract an LPC coefficient, e.g., a 16th-order LPC coefficient, from each frame of the input signal using the Levinson-Durbin algorithm. An excitation signal may be quantized through an adaptive codebook search or a fixed codebook search. The excitation signal may be quantized using an algebraic code excited linear prediction method. Vector quantization may be performed on the gain of the excitation signal using a quantization table having a conjugate structure.

The speech coder illustrated in FIG. 12 includes a linear prediction analysis unit 600, a pitch estimation unit 610, a codebook search unit 620, a line spectrum pair (LSP) unit 630, and a quantization unit 640.

The linear prediction analysis unit 600 performs linear prediction analysis on an input signal using an autocorrelation coefficient that is obtained using an asymmetric window. If a look-ahead period, i.e., the asymmetric window, has a length of 30 ms, the linear prediction analysis unit 600 may perform linear prediction analysis using a 5 ms look-ahead period.

The autocorrelation coefficient is converted into a linear prediction coefficient using the Levinson-Durbin algorithm. For quantization and linear interpolation, the LSP unit 630 converts the linear prediction coefficient into an LSP. The quantization unit 640 quantizes the LSP.

The pitch estimation unit 610 estimates open-loop pitch in order to reduce the complexity of an adaptive codebook search. More specifically, the pitch estimation unit 610 estimates an open-loop pitch period using a weighted speech signal domain of each frame. Thereafter, a harmonic noise shaping filter is configured using the estimated open-loop pitch. Thereafter, an impulse response is calculated using the harmonic noise shaping filter, a linear prediction synthesis filter, and a formant perceptual weighting filter. The impulse response may be used to generate a target signal for the quantization of an excitation signal.

The codebook search unit 620 performs an adaptive codebook search and a fixed codebook search. The adaptive codebook search may be performed in units of sub-frames by calculating an adaptive codebook vector through a closed loop pitch search and through interpolation of past excitation signals. Adaptive codebook parameters may include the pitch period and gain of a pitch filter. The excitation signal may be generated by a linear prediction synthesis filter in order to simplify a closed loop search.

A fixed codebook structure is established based on interleaved single pulse permutation (ISSP) design. A codebook vector comprising 64 positions where 64 pulses are respectively located is divided into four tracks, each track comprising 16 positions. A predetermined number of pulses may be located at each of the four tracks according to transmission rate. Since a codebook index indicates the track location and sign of a pulse, there is no need to store a codebook, and an excitation signal can be generated simply using the codebook index.

The speech coder illustrated in FIG. 12 may perform the above-mentioned coding processes in a time domain. Also, if an input signal is encoded using a linear prediction coding method by the classification module 100 illustrated in FIG. 1, the linear prediction analysis unit 600 may be optional.

The present invention is not restricted to the speech coder illustrated in FIG. 12. In other words, various speech coders, other than the speech coder illustrated in FIG. 12, which can efficiently encode speech signals, may be used within the scope of the present invention.

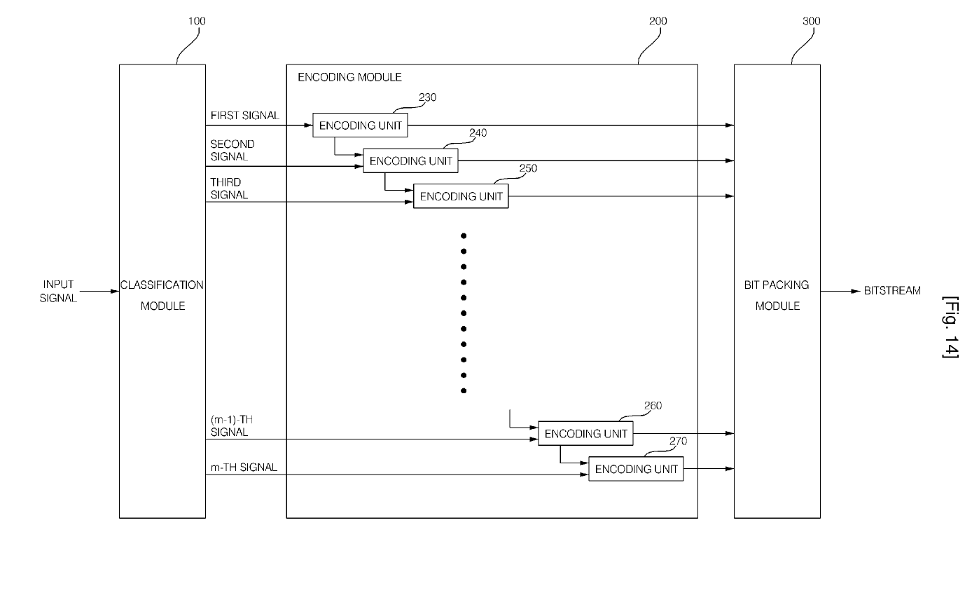

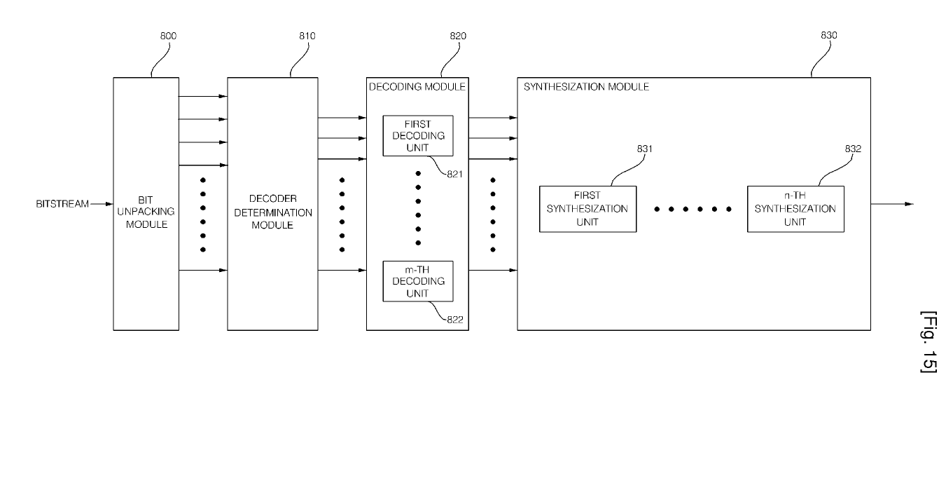

FIG. 13 is a block diagram of another embodiment of one of the first through m-th encoding units 210 and 220 illustrated in FIG. 1. The encoding unit illustrated in FIG. 13 may be an audio encoder.

Referring to FIG. 13, the audio encoder includes a filter bank 700, a psychoacoustic modeling unit 710, and a quantization unit 720.

The filter bank 700 converts an input signal into a frequency-domain signal. The filter bank 700 may perform cosine transform, e.g., modified discrete transform (MDCT), on the input signal.

The psychoacoustic modeling unit 710 calculates a masking threshold of the input signal or the SMR of the input signal. The quantization unit 720 quantizes MDCT coefficients output by the filter bank 700 using the masking threshold calculated by the psychoacoustic modeling unit 710. Alternatively, in order to minimize audible distortion within a given bitrate range, the quantization unit 720 may use the SMR of the input signal.

The audio encoder illustrated in FIG. 13 may perform the above-mentioned encoding processes in a frequency domain.

The present invention is not restricted to the audio encoder illustrated in FIG. 13. In other words, various audio encoders (e.g., advanced audio coders), other than the audio encoder illustrated in FIG. 13, which can efficiently encode audio signals, may be used within the scope of the present invention.

Advanced audio coders perform temporal noise shaping (TNS), intensity/coupling, prediction and middle/side (M/S) stereo coding. TNS is an operation of appropriately distributing time-domain quantization noise in a filter bank window so that the quantization noise can become inaudible. Intensity/coupling is an operation which is capable of reducing the amount of spatial information to be transmitted by encoding an audio signal and transmitting the energy of the audio signal only based on the fact that the perception of the direction of sound in a high band depends mainly upon the time scale of energy.

Prediction is an operation of removing redundancy from a signal whose statistical characteristics do not vary by using the correlation between spectrum components of frames. M/S stereo coding is an operation of transmitting the normalized sum (i.e., middle) and the difference (i.e., side) of a stereo signal instead of left and right channel signals.

A signal that undergoes TNS, intensity/coupling, prediction and M/S stereo coding is quantized by a quantizer that performs Analysis-by-Synthesis (AbS) using an SMR obtained from a psychoacoustic model.

As described above, since an audio encoder encodes an input signal using a modeling method such as a linear prediction coding method, the determination unit 122 illustrated in FIG. 5 may determine whether the input signal can be modeled easily according to a predetermined set of rules. Thereafter, if it is determined that the input signal can be modeled easily, the determination unit 122 may decide to encode the input signal using a speech coder. On the other hand, if it is determined that the input signal cannot be modeled easily, the determination unit 122 may decide to encode the input signal using an audio encoder.

FIG. 14 is a block diagram of an encoding apparatus according to another embodiment of the present invention. In FIGS. 1 through 14, like reference numerals represent like elements, and thus, detailed descriptions thereof will be skipped.

Referring to FIG. 14, a classification module 100 divides an input signal into a plurality of first through n-th divided signals and determines which of a plurality of encoding units 230, 240, 250, 260, and 270 is to be used to encode each of the first through n-th divided signals.

Referring to FIG. 14, the encoding units 230, 240, 250, 260, and 270 may sequentially encode the first through n-th divided signals, respectively. Also, if the input signal is divided into a plurality of frequency band signals, the frequency band signals may be encoded in the order from a lowest frequency band signal to a highest frequency band signal.

In a case where the divided signals are sequentially encoded, an encoding error of a previous signal may be used to encode a current signal. As a result, it is possible to encode the divided signals using different encoding methods and thus to prevent signal distortion and provide bandwidth scalability.

Referring to FIG. 14, the encoding unit 230 encodes the first divided signal, decodes the encoded first divided signal, and outputs an error between the decoded signal and the first divided signal to the encoding unit 240. The encoding unit 240 encodes the second divided signal using the error output by the encoding unit 230. In this manner, the second through m-th divided signals are encoded in consideration of encoding errors of their respective previous divided signals. Therefore, it is possible to realize errorless encoding and enhance the quality of sound.

The encoding apparatus illustrated in FIG. 14 may restore a signal from an input bitstream by inversely performing the operations performed by the encoding apparatus illustrated in FIGS. 1 through 14.

FIG. 15 is a block diagram of a decoding apparatus according to an embodiment of the present invention. Referring to FIG. 15, the decoding apparatus includes a bit unpacking module 800, a decoder determination module 810, a decoding module 820, and a synthesization module 830.

The bit unpacking module 800 extracts, from an input bitstream, one or more encoded signals and additional information that is needed to decode the encoded signals.

The decoding module 820 includes a plurality of first through m-th decoding units 821 and 822 which perform different decoding methods.

The decoder determination module 810 determines which of the first through m-th decoding units 821 and 822 can decode each of the encoded signals most efficiently. The decoder determination module 810 may use a similar method to that of the classification module 100 illustrated in FIG. 1 to determine which of the first through m-th decoding units 821 and 822 can decode each of the encoded signals most efficiently. In other words, the decoder determination module 810 may determine which of the first through m-th decoding units 821 and 822 can decode each of the encoded signals most efficiently based on the characteristics of each of the encoded signals. Preferably, the decoder determination module 810 may determine which of the first through m-th decoding units 821 and 822 can decode each of the encoded signals most efficiently based on the additional information extracted from the input bitstream.

The additional information may include class information identifying a class to which an encoded signal is classified as belonging by an encoding apparatus, encoding unit information identifying an encoding unit used to produce the encoded signal, and decoding unit information identifying a decoding unit to be used to decode the encoded signal.

For example, the decoder determination module 810 may determine to which class an encoded signal belongs based on the additional information and choose, for the encoded signal, whichever of the first through m-th decoding units 821 and 822 corresponding to the class of the encoded signal. In this case, the chosen decoding unit may have such a structure that it can decode signals belonging to the same class as the encoded signal most efficiently.

Alternatively, the decoder determination module 810 may identify an encoding unit used to produce an encoded signal based on the additional information and choose, for the encoded signal, whichever of the first through m-th decoding units 821 and 822 corresponds to the identified encoding unit. For example, if the encoded signal has been produced by a speech coder, the decoder determination module 810 may choose, for the encoded signal, whichever of the first through m-th decoding units 821 and 822 is a speech decoder.

Alternatively, the decoder determination module 810 may identify a decoding unit that can decode an encoded signal based on the additional information and choose, for the encoded signal, whichever of the first through m-th decoding units 821 and 822 corresponds to the identified decoding unit.

Alternatively, the decoder determination module 810 may obtain the characteristics of an encoded signal from the additional information and choose whichever of the first through m-th decoding units 821 and 822 can decode signals having the same characteristics as the encoded signal most efficiently.

In this manner, each of the encoded signals extracted from the input bitstream is encoded by whichever of the first through m-th decoding units 821 and 822 is determined to be able to decode a corresponding encoded signal most efficiently. The decoded signals are synthesized by the synthesization module 830, thereby restoring an original signal.

The bit unpacking module 800 extracts division information regarding the encoded signals, e.g., the number of encoded signals and band information of each of the encoded signals, and the synthesization module 830 may synthesize the decoded signals provided by the decoding module 820 with reference to the division information.

The synthesization module 830 may include a plurality of first through n-th synthesization units 831 and 832. Each of the first through n-th synthesization units 831 and 832 may synthesize the decoded signals provided by the decoding module 820 or perform domain conversion or additional decoding on some or all of the decoded signals.

One of the first through n-th synthesization units 831 and 832 may perform a post-processing operation, which is the inverse of a pre-processing operation performed by an encoding apparatus, on a synthesized signal. Information indicating whether to perform a post-processing operation and decoding information used to perform the post-processing operation may be extracted from the input bitstream.

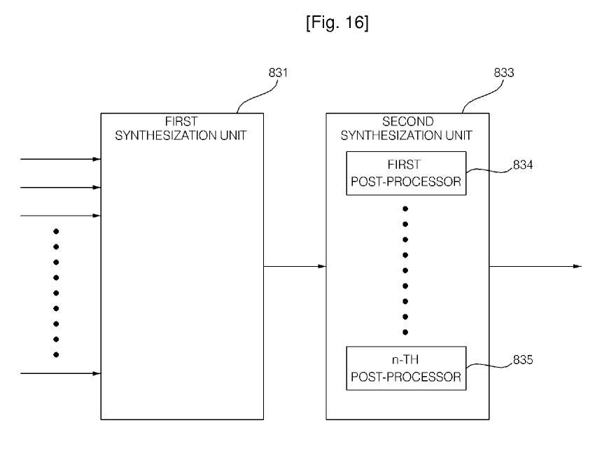

Referring to FIG. 16, one of the first through n-th synthesization units 831 and 832, particularly, a second synthesization unit 833, may include a plurality of first through n-th post-processors 834 and 835. The first synthesization unit 831 synthesizes a plurality of decoded signals into a single signal, and one of the first through n-th post-processors 834 and 835 performs a post-processing operation on the single signal obtained by the synthesization.

Information indicating which of the first through n-th post processors 834 and 835 is to perform a post-processing operation on the single signal obtained by the synthesization may be included in the input bitstream.

One of the first through n-th synthesizers 831 and 832 may perform linear prediction decoding on the single signal obtained by the synthesization using a linear prediction coefficient extracted from the input bitstream, thereby restoring an original signal.

The present invention can be realized as computer-readable code written on a computer-readable recording medium. The computer-readable recording medium may be any type of recording device in which data is stored in a computer-readable manner. Examples of the computer-readable recording medium include a ROM, a RAM, a CD-ROM, a magnetic tape, a floppy disc, an optical data storage, and a carrier wave (e.g., data transmission through the Internet). The computer-readable recording medium can be distributed over a plurality of computer systems connected to a network so that computer-readable code is written thereto and executed therefrom in a decentralized manner. Functional programs, code, and code segments needed for realizing the present invention can be easily construed by one of ordinary skill in the art.

While the present invention has been particularly shown and described with reference to exemplary embodiments thereof, it will be understood by those of ordinary skill in the art that various changes in form and details may be made therein without departing from the spirit and scope of the present invention as defined by the following claims.

### INDUSTRIAL APPLICABILITY

As described above, according to the present invention, it is possible to encode signals having different characteristics at an optimum bitrate by classifying the signals into one or more classes according to the characteristics of the signals and encoding each of the signals using an encoding unit that can best serve the class where a corresponding signal belongs. Therefore, it is possible to efficiently encode various signals including audio and speech signals.

1. A decoding method, comprising:
extracting a plurality of encoded signals from an input bitstream;
determining which of a plurality of decoding methods is to be used to decode each of the encoded signals;
decoding the encoded signals using the determined decoding methods; and
synthesizing the decoded signals.

2. The decoding method of claim 1, further comprising extracting decoding method information regarding how to decode each of the encoded signals,
wherein the determination comprises determining by which of the plurality of decoding methods the encoded signals are to be decoded using the decoding method information.

3. The decoding method of claim 1, wherein the decoding method information comprises at least one of encoding unit information identifying an encoding unit that has produced an encoded signal, decoding unit information identifying a decoding unit that is to decode the encoded signal, and information indicating a characteristic of the encoded signal.

4. The decoding method of claim 1, wherein the determination comprises choosing whichever of the decoding methods can decode each of the encoded signals most efficiently.

5. The decoding method of claim 1, further comprising extracting division information of the encoded signals from the input bitstream,
wherein the synthesization comprises synthesizing the decoded signals into a single signal with reference to the division information.

6. The decoding method of claim 5, wherein the division information comprises a number of encoded signals or frequency band information of the encoded signals.

7. The decoding method of claim 1, further comprising extracting bit quantity information of the encoded signals from the input bitstream,
wherein the decoding comprises decoding the encoded signals according to the bit quantity information.

8. The decoding method of claim 1, further comprising extracting decoding order information of the encoded signals from the input bitstream,
wherein the decoding comprises decoding the encoded signals according to the decoding order information.

9. A decoding apparatus, comprising:
a bit unpacking module which extracts a plurality of encoded signals from an input bitstream;
a decoder determination module which determines which of a plurality of decoding units is to be used to decode each of the encoded signals;
a decoding module which comprises the decoding units and decodes each of the encoded signals using the determined decoding units; and
a synthesization module which synthesizes the decoded signals.

10. The decoding apparatus of claim 9, wherein the bit unpacking module extracts decoding unit information of each of the encoded signals from the input bitstream,
wherein the decoder determination module determines by which of the plurality of decoding units the encoded signals are to be decoded using the decoding unit information.

11. The decoding apparatus of claim 9, wherein the decoder determination module chooses whichever of the decoding units can decode the encoded signals most efficiently.

12. The decoding apparatus of claim 9, wherein the bit unpacking module extracts division information of the encoded signals from the input bitstream,
wherein the synthesization module synthesizes the decoded signals into a single signal with reference to the division information.

13. An encoding method, comprising:
dividing an input signal into a plurality of divided signals;
determining which of a plurality of encoding methods is to be used to encode each of the divided signals based on characteristics of each of the divided signals;
encoding the divided signals using the encoding methods; and
generating a bitstream using the encoded divided signals.

14. The encoding method of claim 13, wherein the determination comprises choosing whichever of the encoding methods can encode the divided signals most efficiently.

15. The encoding method of claim 13, further comprising allocating a bit quantity to encode each of the divided signals.

16. The encoding method of claim 13, further comprising determining an order in which the divided signals are to be encoded.

17. The encoding method of claim 13, further comprising dividing the input signal again into a plurality of divided signals, determining again which of the encoding methods is to be used to encode each of the divided signals, determining again a bit quantity to encode the divided signals or an order in which the divided signals are to be encoded

18. An encoding apparatus, comprising:
a signal division module which divides an input signal into a plurality of divided signals;
an encoder determination module which determines which of a plurality of encoding units is to be used to encode each of the divided signals an encoding module which comprises the encoding units and encodes the divided signals using the determined encoding units; and
a bit packing module which generates a bitstream using the encoded divided signals.

19. The encoding apparatus of claim 18, wherein the encoder determination module chooses whichever of the encoding units can encode the divided signals most efficiently.

20. A computer-readable recording medium having a program for executing the decoding method of any one of claims 1 through 8 or the encoding method of any one of claims 13 through 17.
